(19) United States
(12) Patent Application Publication
(10) Pub. No.: US 2018/0242480 A1
(43) Pub. Date: Aug. 23, 2018

(54) SHIELD COVER FOR PARTICLE SENSOR TO IMPROVE ELECTROMAGNETIC INTERFERENCE PERFORMANCE

(71) Applicant: Honeywell International Inc., Morris Plains, NJ (US)

(72) Inventors: Kai Liu, Nanjing (CN); Tao Chen, Shanghai (CN); Peipei Liu, Nanjing (CN); Tong Shang, Denville, NJ (US); Ouyang Yang, Shanghai (CN)

(21) Appl. No.: 15/436,036

(22) Filed: Feb. 17, 2017

(51) Int. Cl. H05K 9/00; G01N 15/06

(52) U.S. Cl. CPC H05K 9/0058; G01N 2015/0693; G01N 15/06

(57) ABSTRACT

Embodiments relate generally to systems and methods for dissipating electric charge within a particulate matter sensor, and reducing the effects of electromagnetic interference within the particulate matter sensor. A particulate matter sensor may comprise an airflow channel; a light source configured to pass light through the airflow channel; a photodetector configured to receive light from the light source after it passes through the airflow channel; a printed circuit board coupled to the photodetector having a processor and a memory storing instructions which, when executed by the processor, determines an indication of a mass concentration of particles in the airflow channel based on an output of the photodetector; and a shield cover configured to attach to and cover at least a portion of the printed circuit board, and configured to reduce the effects of electromagnetic interference within the particulate matter sensor.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

A particulate matter sensor or dust sensor may be used to determine a quality of air, for example in a quality of air that is input to and/or output from an air cleaner. In some industrialized regions, environmental air may have high concentrations of particulate matter of different sizes. If the concentration of such particulate matter is high enough, it may be deleterious to human health. Consumers may wish to purchase and install air cleaners for the residences to improve the quality of air breathed in the home. Such consumer grade air cleaners may desirably be modestly priced and compact in size.

### SUMMARY

In an embodiment, a particulate matter sensor may comprise an airflow channel; a light source configured to pass light through the airflow channel; a photodetector configured to receive light from the light source after it passes through the airflow channel; a printed circuit board coupled to the photodetector having a processor and a memory storing instructions which, when executed by the processor, determines an indication of a mass concentration of particles in the airflow channel based on an output of the photodetector; and a shield cover configured to attach to and cover at least a portion of the printed circuit board, and configured to reduce the effects of electromagnetic interference within the particulate matter sensor.

In an embodiment, a method for dissipating the electric charge within a particulate matter sensor may comprise providing a printed circuit board configured to interact with elements of the particulate matter sensor; attaching a shield cover to the printed circuit board at a plurality of connection points between the shield cover and the printed circuit board; assembling a housing of the particulate matter sensor over the printed circuit board and the shield cover; powering the printed circuit board; and dissipating electric charges that can cause electromagnetic interference from the printed circuit board through the shield cover.

In an embodiment, a particulate matter sensor may comprise an airflow channel; a light source configured to pass light through the airflow channel; a photodetector configured to receive light from the light source that is scattered by particulate matter within the airflow channel; a printed circuit board coupled to the photodetector having a processor and a memory storing instructions which, when executed by the processor, determines an indication of a mass concentration of particle matter in the airflow channel based on an output of the photodetector; a shield cover configured to attach to and cover at least a portion of a first side of the printed circuit board, and configured to dissipate electric charges from one or more elements of the particulate matter sensor; and a light source cover configured to attach to a second side of the printed circuit board, configured to contain the light source, and configured to dissipate electric charges from one or more elements of the particulate matter sensor.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 illustrates an exploded view of a particulate matter sensor according to an embodiment of the disclosure.

FIG. 2 illustrates an assembled view of elements of a particulate matter sensor according to an embodiment of the disclosure.

FIG. 3 illustrates an assembled particulate matter sensor according to an embodiment of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The following brief definition of terms shall apply throughout the application:

The term “comprising” means including but not limited to, and should be interpreted in the manner it is typically used in the patent context;

The phrases “in one embodiment,” “according to one embodiment,” and the like generally mean that the particular feature, structure, or characteristic following the phrase may be included in at least one embodiment of the present invention, and may be included in more than one embodiment of the present invention (importantly, such phrases do not necessarily refer to the same embodiment);

If the specification describes something as “exemplary” or an “example,” it should be understood that refers to a non-exclusive example;

The terms “about” or “approximately” or the like, when used with a number, may mean that specific number, or alternatively, a range in proximity to the specific number, as understood by persons of skill in the art field; and

If the specification states a component or feature “may,” “can,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some embodiments, or it may be excluded.

Embodiments of the disclosure include systems and methods for reducing the effects of electromagnetic interference (EMI) within a particulate matter sensor. Typical particulate matter sensors may use a light source and a fan structure to direct airflow through the light source. A photodetector may detect scatter light from particulate matter in the airflow through the sensor. The elements of the particulate matter sensor may be controlled by a printed circuit board (PCB).

EMI is a disturbance generated by an external source that affects an electrical circuit by electromagnetic induction, electrostatic coupling, or conduction. The disturbance may degrade the performance of the circuit or even stop it from functioning. In the case of a data path, these effects can range from an increase in error rate to a total loss of the data.

Particulate matter sensors, particularly those used in indoor air cleaners and air conditioning systems, may require improved EMI performance. Typical particulate matter sensors may attempt to reduce the effects of EMI by mounting a metal shield cover on the exterior of the plastic housing of the sensor. The external shield cover may contact a ground electrode of a PCB within the sensor via a spring. However, this method of grounding the PCB may provide only single-point grounding which may not ensure equal voltage levels across the shield cover. Additionally, single-point grounding creates only one path and a high resistance loop for the dissipation of electric charge from the PCB. Also, the contact resistance of the spring may also increase the loop resistance. Another disadvantage to a typical external shield cover is the exposure of the PCB due to the connection point between the PCB and the shield cover, causing a part of the PCB to be exposed to the external environment, decreasing the shielding effects. Also, typical particulate matter sensors may have a plastic cover for the light source (or laser), which may not provide any protection from EMI.

Embodiments of the disclosure include a metal shield cover that is mounted on the interior of the housing of the particulate matter sensor. The shield cover may fit over at least a portion of the PCB, covering the electric circuit, and may be soldered directly to the PCB. The shield cover may be soldered to the PCB in multiple locations, to provide multi-point grounding. The multi-point grounding may ensure equal voltage across the shield cover, stabilizing the ground plane of the sensor. Also, multi-point grounding creates multiple grounding paths and a low resistance loop for dissipation of electric charge. The shield cover may also fit closely to the surface of the PCB, thereby isolating the routings and components from external electromagnetic interference.

Embodiments may also include a light source cover configured to prevent EMI. The light source cover may comprise aluminum, and may enclose the light source and/or the photodetector. The light source cover may also attach to the PCB.

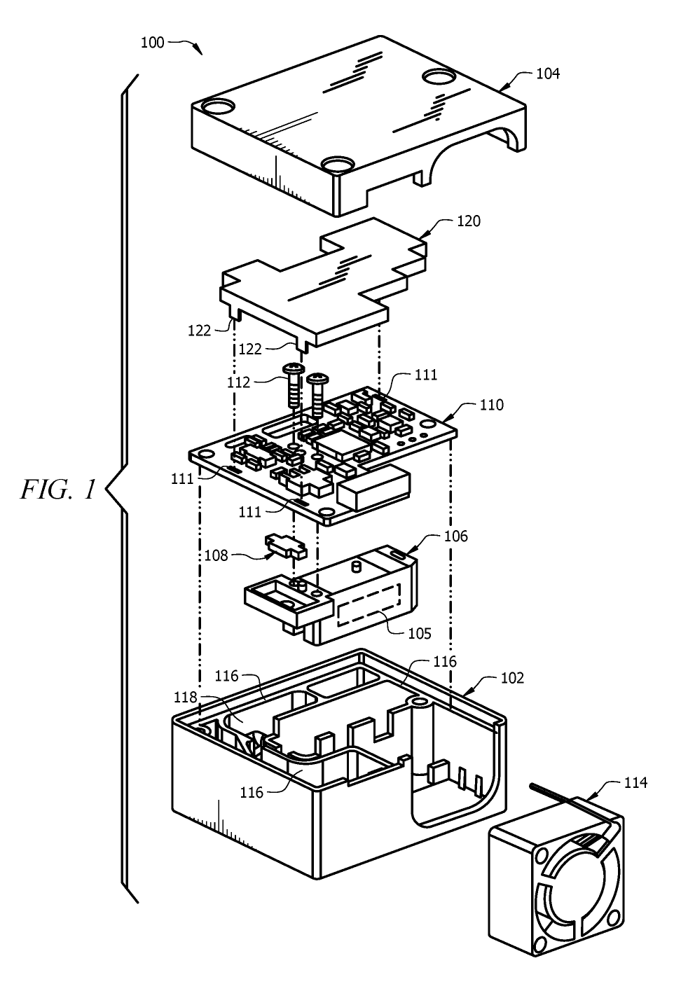

FIG. 1 illustrates an exploded view of a particulate matter sensor 100. The sensor 100 may comprise a lower housing 102 and an upper housing 104, where the upper housing 104 may also be referred to as a cover or top. The lower housing 102 may comprise interior walls 116 forming an airflow channel 118 through the lower housing 102. Airflow may be directed through the airflow channel 118 by an airflow generator 114, which may comprise a fan. The airflow channel 118 may direct the airflow through a beam produced by a light source 105, such that particulate matter in the airflow may pass through the light source 105 and scatter a portion of the light produced by the light source 105. The light source 105 may be contained in a light source cover 106, wherein the light source cover 106 may comprise a metal material. In some embodiments, the light source cover 106 may comprise aluminum.

The sensor 100 may comprise a photodetector 108 configured to detect light that is scattered by the particulate matter in the airflow channel 118. In some embodiments, the photodetector 108 may be located proximate to the light source cover 106. In some embodiments, the light source cover 106 may comprise a recess configured to receive and hold the photodetector 108 in place within the sensor 100. The light source cover 106 may be held in place within the lower housing 102 by one or more walls 116.

The sensor 100 may comprise a PCB 110 configured to control the elements of the sensor, receive information from the photodetector 108, control the airflow generator 114, and control the output of the light source 105, among other processing and controls. The PCB 110 may be attached to the light source cover 106 via one or more screws 112. The PCB 110 may be configured to contact the photodetector 108 and the light source cover 106. In some embodiments, the photodetector 108 may be enclosed by the light source cover 106 and the PCB 110.

The sensor 100 may comprise a shield cover 120 configured to reduce the effects of EMI within the sensor 100. The shield cover 120 may comprise one or more tabs 122 configured to contact and fit into openings 111 of the PCB 110. In some embodiments, the shield cover 120 may be soldered to the PCB 110 at the tabs 122 and openings 111. In some embodiments, the shield cover 120 may cover but not contact any other elements on the PCB 110, except at the openings 111. The shield cover 120 may be shaped to fit over the components of the PCB 110. In some embodiments, the shield cover 120 may comprise a top surface and side walls, wherein the side walls may extend toward the PCB 110 and may cover the components of the PCB 110 when installed

The shield cover 120 may comprise a metal material suitable for dissipating electric charge. The shield cover 120 may comprise a metal material, for example. In some embodiments, the shield cover 120 may comprise Carobronze. The shield cover 120 may be directly soldered to the PCB 110 via the tabs 122.

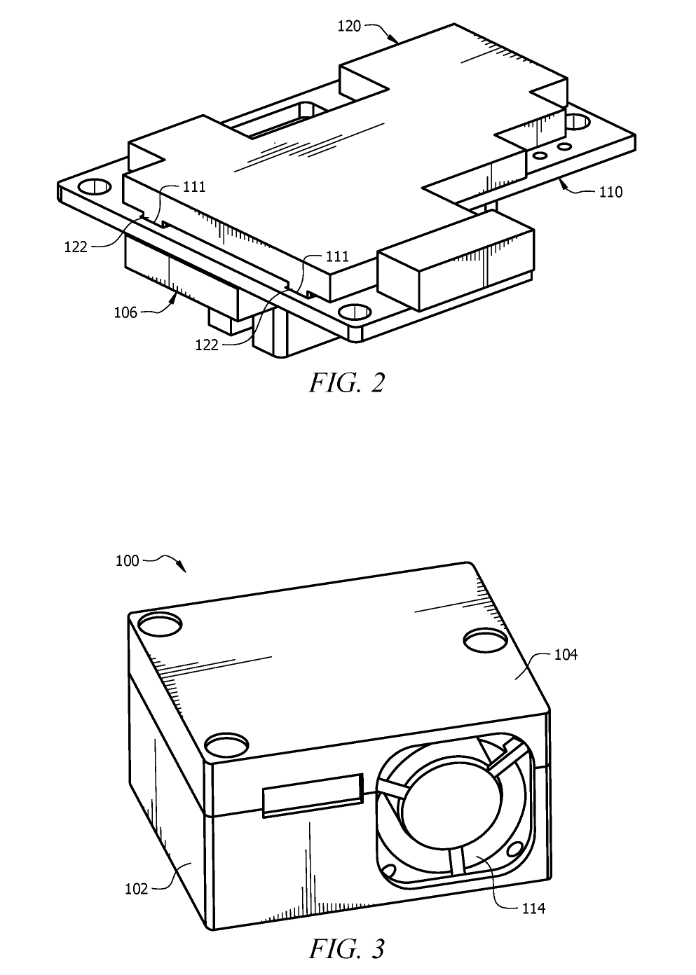

FIG. 2 illustrates an assembled view of the PCB 110, light source cover 106, and shield cover 120. As described above, the shield cover 120 may fit over the components of the PCB 110, and may be soldered to the PCB 110 at the tabs 122.

FIG. 3 illustrates a perspective view of an assembled particulate matter sensor 100.

In a first embodiment, a particulate matter sensor may comprise an airflow channel; a light source configured to pass light through the airflow channel; a photodetector configured to receive light from the light source after it passes through the airflow channel; a printed circuit board coupled to the photodetector having a processor and a memory storing instructions which, when executed by the processor, determines an indication of a mass concentration of particles in the airflow channel based on an output of the photodetector; and a shield cover configured to attach to and cover at least a portion of the printed circuit board, and configured to reduce the effects of electromagnetic interference within the particulate matter sensor.

A second embodiment can include the particulate matter sensor of the first embodiment, wherein the shield cover comprises a plurality of tabs configured to attach to a plurality of openings in the printed circuit board.

A third embodiment can include the particulate matter sensor of the first or second embodiments, wherein the shield cover is soldered to the printed circuit board, creating at least two points of connection between the shield cover and the printed circuit board.

A fourth embodiment can include the particulate matter sensor of any of the first to third embodiments, wherein the printed circuit board comprises a first side and a second side, wherein the first side of the printed circuit board couples with the photodetector, and wherein the second side attaches to the shield cover.

A fifth embodiment can include the particulate matter sensor of any of the first to fourth embodiments, further comprising a housing, wherein the shield cover is located within the housing.

A sixth embodiment can include the particulate matter sensor of any of the first to fifth embodiments, further comprising a light source cover configured to contain the light source, wherein the printed circuit board attaches to the light source cover.

A seventh embodiment can include the particulate matter sensor of the sixth embodiment, wherein the light source cover comprises a recess configured to hold the photodetector between the light source cover and the printed circuit board.

An eighth embodiment can include the particulate matter sensor of any of the first to seventh embodiments, wherein the photodetector is configured to detect light scattered off of particulate matter in the airflow in the airflow channel.

A ninth embodiment can include the particulate matter sensor of any of the first to eighth embodiments, wherein the shield cover comprises Carobronze.

In a tenth embodiment, a method for dissipating the electric charge within a particulate matter sensor may comprise providing a printed circuit board configured to interact with elements of the particulate matter sensor; attaching a shield cover to the printed circuit board at a plurality of connection points between the shield cover and the printed circuit board; assembling a housing of the particulate matter sensor over the printed circuit board and the shield cover; powering the printed circuit board; and dissipating electric charges that can cause electromagnetic interference from the printed circuit board through the shield cover.

An eleventh embodiment can include the method of the tenth embodiment, wherein the shield cover is located on the interior of the housing of the particulate matter sensor.

A twelfth embodiment can include the method of the tenth or eleventh embodiments, further comprising containing a light source within a light source cover; and attaching the light source cover to the printed circuit board, wherein the light source cover is attached to a first side of the printed circuit board, and wherein the shield cover is attached to a second side of the printed circuit board.

A thirteenth embodiment can include the method of the twelfth embodiment, further comprising containing a photodetector between the printed circuit board and the light source cover.

A fourteenth embodiment can include the method of the twelfth or thirteenth embodiments, wherein the light source cover comprises aluminum, and the method further comprising dissipating electric charges that can cause electromagnetic interference from the printed circuit board through the light source cover.

A fifteenth embodiment can include the method of any of the tenth to fourteenth embodiments, wherein attaching the shield cover to the printed circuit board comprises soldering the shield cover to the printed circuit board, forming at least two connection points.

In a sixteenth embodiment, a particulate matter sensor may comprise an airflow channel; a light source configured to pass light through the airflow channel; a photodetector configured to receive light from the light source that is scattered by particulate matter within the airflow channel; a printed circuit board coupled to the photodetector having a processor and a memory storing instructions which, when executed by the processor, determines an indication of a mass concentration of particle matter in the airflow channel based on an output of the photodetector; a shield cover configured to attach to and cover at least a portion of a first side of the printed circuit board, and configured to dissipate electric charges from one or more elements of the particulate matter sensor; and a light source cover configured to attach to a second side of the printed circuit board, configured to contain the light source, and configured to dissipate electric charges from one or more elements of the particulate matter sensor.

A seventeenth embodiment can include the particulate matter sensor of the sixteenth embodiment, wherein the light source cover comprises aluminum.

An eighteenth embodiment can include the particulate matter sensor of the sixteenth or seventeenth embodiments, wherein the shield cover comprises Carobronze.

A nineteenth embodiment can include the particulate matter sensor of any of the sixteenth to eighteenth embodiments, wherein the photodetector is contained between the printed circuit board and the light source cover.

A twentieth embodiment can include the particulate matter sensor of any of the sixteenth to nineteenth embodiments, wherein the shield cover is soldered to the printed circuit board, creating at least two points of connection between the shield cover and the printed circuit board.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above, but is defined by the claims which follow, that scope including all equivalents of the subject matter of the claims. Each and every claim is incorporated as further disclosure into the specification and the claims are embodiment(s) of the present invention(s). Furthermore, any advantages and features described above may relate to specific embodiments, but shall not limit the application of such issued claims to processes and structures accomplishing any or all of the above advantages or having any or all of the above features.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure. Specifically and by way of example, although the headings might refer to a “Field,” the claims should not be limited by the language chosen under this heading to describe the so-called field. Further, a description of a technology in the “Background” is not to be construed as an admission that certain technology is prior art to any invention(s) in this disclosure. Neither is the “Summary” to be considered as a limiting characterization of the invention(s) set forth in issued claims.

Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of the claims shall be considered on their own merits in light of this disclosure, but should not be constrained by the headings set forth herein.

Use of broader terms such as “comprises,” “includes,” and “having” should be understood to provide support for narrower terms such as “consisting of,” “consisting essentially of,” and “comprised substantially of.” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

1. A particulate matter sensor comprising:
an airflow channel;
a light source configured to pass light through the airflow channel;
a photodetector configured to receive light from the light source after it passes through the airflow channel;
a printed circuit board coupled to the photodetector having a processor and a memory storing instructions which, when executed by the processor, determines an indication of a mass concentration of particles in the airflow channel based on an output of the photodetector; and
a shield cover mounted to the printed circuit board in multiple locations to provide multi-point grounding and to cover at least a portion of the printed circuit board, and configured to reduce the effects of electromagnetic interference within the particulate matter sensor;
wherein the shield cover comprises a metal material suitable for dissipating electric charge.

2. The particulate matter sensor of claim 1, wherein the shield cover comprises a plurality of tabs configured to attach to a plurality of openings in the printed circuit board.

3. The particulate matter sensor of claim 1, wherein the shield cover is soldered to the printed circuit board, creating at least two points of connection between the shield cover and the printed circuit board.

4. The particulate matter sensor of claim 1, wherein the printed circuit board comprises a first side and a second side, wherein the first side of the printed circuit board couples with the photodetector, and wherein the second side attaches to the shield cover.

5. The particulate matter sensor of claim 1, further comprising a housing, wherein the shield cover is located within the housing, and wherein multi-point grounding of the shield cover is configured to ensure equal voltage across the shield cover.

6. The particulate matter sensor of claim 1, further comprising a light source cover configured to contain the light source, wherein the printed circuit board attaches to the light source cover.

7. The particulate matter sensor of claim 6, wherein the light source cover comprises a recess configured to hold the photodetector between the light source cover and the printed circuit board.

8. The particulate matter sensor of claim 1, wherein the photodetector is configured to detect light scattered off of particulate matter in the airflow in the airflow channel.

9. The particulate matter sensor of claim 1, wherein the shield cover comprises Carobronze.

10. A method for dissipating the electric charge within a particulate matter sensor, the method comprising:
providing a printed circuit board configured to interact with elements of the particulate matter sensor;
attaching a metal shield cover to the printed circuit board at a plurality of connection points between the shield cover and the printed circuit board to provide multi-point grounding and to cover at least a portion of the printed circuit board; and
assembling a housing of the particulate matter sensor over the printed circuit board and the shield cover.

11. The method of claim 10, wherein multi-point grounding of the shield cover ensures equal voltage across the shield cover.

12. The method of claim 10, further comprising containing a light source within a light source cover; and attaching the light source cover to the printed circuit board, wherein the light source cover is attached to a first side of the printed circuit board, and wherein the shield cover is attached to a second side of the printed circuit board.

13. The method of claim 12, further comprising containing a photodetector between the printed circuit board and the light source cover.

14. The method of claim 12, wherein the light source cover comprises aluminum, and the method further comprising dissipating electric charges that can cause electromagnetic interference from the printed circuit board through the light source cover, and dissipating electric charges that can cause electromagnetic interference from the printed circuit board through the shield cover.

15. The method of claim 10, wherein attaching the shield cover to the printed circuit board comprises soldering the shield cover to the printed circuit board, forming at least two connection points.

16. A particulate matter sensor comprising:
an airflow channel;
a light source configured to pass light through the airflow channel;
a photodetector configured to receive light from the light source that is scattered by particulate matter within the airflow channel;
a printed circuit board coupled to the photodetector having a processor and a memory storing instructions which, when executed by the processor, determines an indication of a mass concentration of particle matter in the airflow channel based on an output of the photodetector;
a shield cover mounted to the printed circuit board in multiple locations to provide multi-point grounding and to cover at least a portion of a first side of the printed circuit board, and configured to dissipate electric charges from one or more elements of the particulate matter sensor; and
a light source cover configured to attach to a second side of the printed circuit board, configured to contain the light source, and configured to dissipate electric charges from one or more elements of the particulate matter sensor;
wherein the shield cover comprises a metal material suitable for dissipating electric charge.

17. The particulate matter sensor of claim 16, wherein the light source cover comprises aluminum.

18. The particulate matter sensor of claim 16, wherein the shield cover comprises Carobronze.

19. The particulate matter sensor of claim 16, further comprising a housing, wherein the shield cover is located within the housing, and wherein multi-point grounding of the shield cover is configured to ensure equal voltage across the shield cover: and wherein the photodetector is contained between the printed circuit board and the light source cover.

20. The particulate matter sensor of claim 16, wherein the shield cover is soldered to the printed circuit board, creating at least two points of connection between the shield cover and the printed circuit board.
